(19) United States
(12) Patent Application Publication
(10) Pub. No.: US 2020/0146119 A1
(43) Pub. Date: May 7, 2020

(54) Wirelessly Controllable Lighting Modules

(71) Applicant: Intematix Corporation, Fremont, CA (US)

(72) Inventor: Yi-Qun Li, Danville, CA (US)

(21) Appl. No.: 16/673,396

(22) Filed: Nov. 4, 2019

Related U.S. Application Data
(60) Provisional application No. 62/755,888, filed on Nov. 5, 2018.

(51) Int. Cl. H05B 37/02; H05B 33/08; H01L 33/50; H01L 33/46; H01L 25/075

(52) U.S. Cl. CPC H05B 37/0272; H05B 33/0812; H05B 33/0857; H05B 33/0824; H01L 33/46; H01L 25/0753; H01L 33/50

(57) ABSTRACT

A lighting module may include a two color/color temperature LED array including first LEDs that generate light of a first color/color temperature; second LEDs that generate light of a second color/color temperature; a first LED driver for operating the first LEDs in response to a first control signal; a second LED driver for operating the second LEDs in response to a second control signal; a wireless controller for generating the first and second control signals in response to a control signal wirelessly receivable from a remote device; and a circuit board. The first and second LEDs, the first and the second LED drivers and the wireless controller may be mounted on the circuit board.

This patent application is a utility of U.S. Provisional Patent Application Ser. No. 62/755,888, filed on Nov. 5, 2018, which is hereby incorporated by reference in its entirety.

### FIELD OF THE INVENTION

Embodiments of the present invention are directed to wirelessly controllable lighting modules. More particularly, although not exclusively, embodiments concern LED lighting modules whose color/color temperature and/or brightness can be wirelessly controlled.

### BACKGROUND OF THE INVENTION

White light emitting LEDs (“white LEDs”) include one or more photoluminescence materials (typically inorganic phosphor materials), which absorb a portion of the blue light emitted by the LED and re-emit light of a different color (wavelength). The portion of the blue light generated by the LED that is not absorbed by the phosphor material combined with the light emitted by the phosphor provides light which appears to the eye as being white in color. Due to their long operating life expectancy (>50,000 hours) and high luminous efficacy (100 lumens per watt and higher), white LEDs are rapidly replacing conventional fluorescent, compact fluorescent and incandescent lamps.

LED drivers (power regulators) are used in virtually every LED lighting application with their basic function being to convert supplied power, either AC or DC, to a DC constant current output that is used to drive (operate) the LED. Some LED drivers operate at a fixed constant output current that can be set using switches or externally connected resistors. However, in applications where it is required for the light output to be dimmable and/or the color temperature of the light output to be controllable, this requires an LED driver having a variable constant output current (typically, the output current of such an LED driver can be set via a wired or wireless programming interface). In such applications, for example, a controller can be used to regulate the input power to the LED driver (e.g. triac dimmers) for dimming or a control module can regulate the output current in response to a control signal applied to a control input of the LED driver for dimming/color control. In the lighting industry, the most common control inputs for dimming are 0-10V analog input and Digital Addressable lighting Interface (DALI)—a digital input.

With wider adoption of solid state lighting (SSL) and general cost reduction of LEDs, the lighting industry is beginning to exploit other benefits of SSL including white point tuning (CCT tuning and/or color tuning) and wireless controls for implementation of lighting into IoT (Internet Of Things) installations such as smart home, smart office, etc. The Internet of Things refers to the ever-growing network of physical objects that feature an IP address for internet connectivity, and the communication that occurs between these objects and other Internet-enabled devices and systems.

White point tuning or color tuning requires LEDs of at least two colors/color temperatures that are independently controllable thereby requiring at least two LED channels. Typically, LED drivers are implemented as part of the power supply and housed in some form of enclosure separate from the LEDs and controller circuitry. Electrical connections between the driver PCB and other system components (LEDs controller) are generally made using wires either soldered to the PCB (flying leads) or mated to the PCB through some form of terminal block. The number of electrical connections grows as the number of LED channels is increased in order to implement SSL features such as white point or full color tuning. With the additional wiring connections comes increased risk of incorrect wiring during fabrication or installation of the lighting module and/or the possibility of one of the connections failing during transportation, installation or operation of the lighting module. Either scenario can result in failure of the lighting module to operate correctly and may result in damage to the lighting module, its components or surroundings thereby increasing cost in the maintenance of the lighting module.

Another problem with the known lighting modules described above, is that their large physical size restricts their use to lighting fixtures such as down lights or troffers, and prevents their use in small form factor lamps such as an A-series light bulb.

Typical lighting modules suffer from problems associated with the compactness of the LEDs on the circuit board which can cause inefficiencies of manufacture and overall output of the module. Moreover, typical lighting modules can be structurally very complex which can lead to problems and additional costs during manufacture thereof. For example, since typical lighting modules contain many separate components, this increases the likelihood of failure during manufacture and general robustness of the module after manufacture. Another problem encountered with typical lighting modules is usage of excess wiring, as discussed above, that can lead to faults during fabrication or installation of the lighting module.

The present invention arose in an endeavor to provide a lighting module, optionally a wirelessly controllable lighting module, that at least in part overcomes the limitation of the known lighting modules.

### SUMMARY OF THE INVENTION

According to an aspect of the present invention, there is provided a lighting module comprising: a plurality of first LEDs operable to generate light of a first color temperature; a plurality of second LEDs operable to generate light of a second color temperature; a first LED driver for operating the plurality of first LEDs in response to a first control signal; a second LED driver for operating the plurality of second LEDs in response to a second control signal; a wireless controller for generating the first and second control signals in response to a control signal wirelessly receivable from a remote device; and a circuit board; wherein the plurality of first and second LEDs, the first and the second LED drivers and the wireless controller are mounted on the circuit board.

An advantage of the present invention is the provision of a lighting module which incorporates its components on a circuit board, for instance the same circuit board or a single circuit board. In this way, where the components such as the plurality of first and second LEDs, the first and second LED drivers, and the wireless controller are incorporated or mounted on a circuit board, this enables the design of the lighting module as a whole to be more compact than known lighting modules. More particularly, it may be that the first and second LEDs can be arranged in a more compact manner than with known arrangements of typical lighting modules. This can lead to improvements in enhanced efficiencies of manufacturing the lighting module in terms of time and cost. The output efficiency of the lighting module can also be improved in this manner. Furthermore, by designing a lighting module according to an embodiment of the present invention the structural complexity of the lighting module can be reduced thus reducing the likelihood of encountering faults during manufacture and malfunction following manufacture. For example, robustness of the module following manufacture can be enhanced in this way by virtue of the reduction of separate components (that is where the plurality of first and second LEDs, the first and the second LED drivers and the wireless controller are mounted on the circuit board, for instance the same or single circuit board). Another problem addressed and/or overcome by a lighting module formed according to the present invention is the reduction in use of excess wiring, which has the effect of reducing faults during fabrication or installation of the lighting module.

It may be that the first and second LED drivers comprise a linear regulator. This may encompass a first and second linear regulator, for instance. The linear regulator may operate in a current control mode. In this specification, a “linear” power regulator/driver is defined as a power regulator that operates in a current control mode and produces a constant-current output. A linear regulator is to be contrasted with a “switching” regulator that operates in a constant power control mode (e.g. a switch mode power supply) that produces a switched (modulated) output current. This means that the power conversion of the first and second LED drivers is through linear regulation at a constant current.

Since the drivers and the wireless controller are mounted on a circuit board in close proximity, if a switching regulator (having a conversion efficiency of typically 90%) is used this may interfere with operation of the wireless control due to noise generated by the switching regulator. Thus, while the conversion efficiency of a linear regulator, typically having a conversion efficiency of 65%, is lower than a switching regulator that operates at constant power (such as a switch mode power supply) and therefore consumes more power, since a linear regulator is not switching between on and off states it does not generate a signal which interferes with operation of the wireless controller. This is highly advantageous.

Of course, it will be appreciated that, in other embodiments, a switching regulator may be used in order to reduce power consumption. This may involve a screening process to prevent interference of the operation of the wireless controller.

It may be that the first LEDs comprise unpackaged first LED chips that have an individual coating layer of a first photoluminescence material covering one or more light emitting faces of the unpackaged first LED chips. The LEDs may be in form of “chip-scale packaging”. More particularly, the photoluminescence material may be in the form of a film or sheet containing the photoluminescence material(s) (e.g. a silicone sheet incorporating one or more phosphor materials) which is laminated over at least a top face (and optionally side faces) of the LED chip.

The individual coating layer may be in contact with and covers the top and side light emitting faces of the unpackaged first LED chip.

The first LEDs may comprise a light reflective material covering the side light emitting face of the unpackaged first LED chip, and wherein the individual coating layer may be in contact with and covers the top light emitting face of the unpackaged first LED chip.

Similarly, it may be that the second LEDs comprise unpackaged second LED chips that have an individual coating layer of a second photoluminescence material covering one or more light emitting faces of the unpackaged second LED chips.

The individual coating layer may be in contact with and covers the top and side light emitting faces of the unpackaged second LED chip.

In this way, the LED module may comprise a light reflective material covering the side light emitting face of the unpackaged second LED chip, and wherein the individual coating layer may be in contact with and covers the top light emitting face of the unpackaged second LED chip.

An advantage of chip-scale packaging is that it lends itself to mounting large numbers of LEDs with a higher packing density—making the lighting module and arrangement of the LEDs more compact which is a significant improvement over known lighting modules.

The first and second LEDs may be mounted directly on the circuit board. Alternatively, or additionally, it will be understood that the first and second LEDs may comprise an assembly having first and second LEDs mounted on a substrate (submount) to form a so-called SMD (Surface Mount Device) LED module and the substrate of the SMD LED module is mounted on the circuit board. The first and second LEDs may be mounted on the substrate in pairs and the substrate include respective contact pads for the anode and cathode of the first and second LEDs enabling independent operation of the first and second LEDs.

It may be that the assembly consists of two LEDs mounted on the substrate. This arrangement may be particularly advantageous because it enables more uniform color emission rather than having groups of first LEDs separated from second LEDs as is typical in known arrangements of lighting modules.

The plurality of first LEDs may be operable to generate Cool White (CW) light, and the plurality of second LEDs may be operable to generate Warm White (WW) light. In this patent specification, Cool White is defined as white light having a CCT (Correlated Color Temperature) of between about 4500K to about 6000K and Warm White is defined as white light having a CCT of between about 2700K to about 4000K.

The Cool White light may have a color temperature of 5000K to 5500K.

The warm white light may have a color temperature of 2700K to 3000K.

The plurality of first LEDs and plurality of second LEDs may be configured as an array.

The array may comprise rows and columns and wherein rows comprise alternating first and second LEDs. This enables a more uniform color emission rather than having groups of first LEDs separated from second LEDs as found in typical arrangements.

The array may comprise rows and columns and wherein columns comprise alternating first and second LEDs. This enables a more uniform color emission rather than having groups of first LEDs separated from second LEDs as found in typical arrangements.

The array may comprise rows and columns and wherein rows and columns comprise alternating first and second LEDs. This enables a more uniform color emission rather than having groups of first LEDs separated from second LEDs as found in typical arrangements.

It may be that first control signal is an analog voltage and the first LED driver is configured to receive said first analog voltage control signal from a wireless controller.

The second control signal may be an analog voltage and the second LED driver may be configured to receive said second analog voltage control signal from a wireless controller.

It may be that the first control signal is digital and the first LED driver is configured to receive said first digital control signal from a wireless controller.

The second control signal may be digital and the second LED driver may be configured to receive said second digital control signal from a wireless controller.

The circuit board may comprise an MCPCB (Metal Core Printed Circuit Board). The components of the lighting module may be applied to the same face of the metal core printed circuit board.

The wireless controller may comprise an antenna, a transceiver, and a control module.

It may be that the antenna, the transceiver, and control module are mounted on a substrate, and wherein the substrate is mounted on the circuit board. The substrate may be considered another component that is mounted on the circuit board. In this way, the components such as the plurality of first and second LEDs, the first and the second LED drivers and said substrate may all be mounted on the circuit board, such as the same or single circuit board.

The wireless controller may controllably adjust the first and second control signals such that the LED module generates light with a selected dimming level and/or selected color temperature.

It may be that the wireless controller wirelessly communicates with a remote device using a Bluetooth protocol.

It may be that the wireless controller wirelessly communicates with a remote device using a Wi-Fi protocol.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a block diagram of a wirelessly controllable LED module according to embodiments of the invention;

FIG. 2 is a block diagram of a linear LED driver;

FIG. 3 is a schematic representation of a two color LED array;

FIGS. 4a and 4b are schematic cross-sectional views of two configurations of “chip-scale packaged” LEDs;

FIGS. 5a and 5b are schematic representations of an SMD LED module respectively showing a top view and a cross section side view through A-A;

FIGS. 5c to 5e are schematic representations of a substrate (submount) of the SMD LED module of FIGS. 5a and 5b that respectively show a view of the upper face of the substrate, a view of the lower face of the substrate and a side cross section view through B-B;

FIG. 6 is a circuit diagram of a wirelessly controllable LED module according to some embodiments; and

FIG. 7 is a plan view of a physical implementation of the wirelessly controllable LED module of FIG. 6.

### DETAILED DESCRIPTION OF THE INVENTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration. Throughout this specification like reference numerals are used to denote like parts.

Embodiments of the invention concern wirelessly controllable lighting modules comprising a plurality of first color/color temperature LEDs; a plurality of second color/color temperature LEDs; a first LED driver for operating the plurality of first color LEDs in response to a first control signal; a second LED driver for operating the plurality of second color LEDs in response to a second control signal; a wireless controller for generating the first and second control signals in response to a control signal wirelessly received from a remote device; and a circuit board; wherein the plurality of first and second LEDs, the first and the second LED drivers and the wireless controller are mounted on the circuit board.

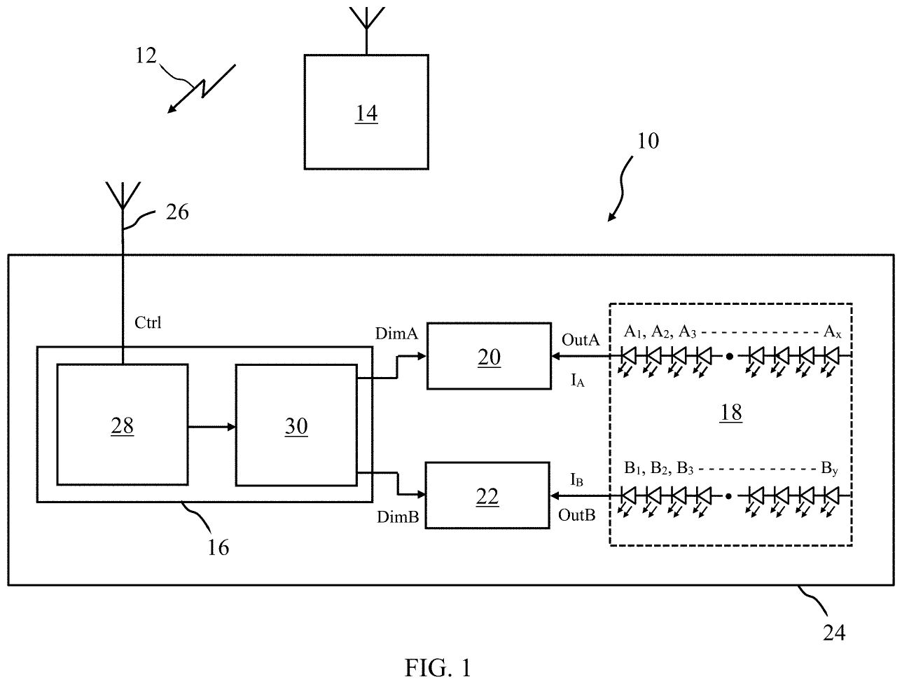

Referring to FIG. 1, there is shown a block diagram of a wirelessly controllable lighting module 10 according to an embodiment of the invention. The color/color temperature and brightness (dimming level) of light generated by the lighting module 10 can be wirelessly controlled in response to a wireless control signal 12 (Ctrl) received from a remote device 14. The lighting module 10 is intended to be compact enough to be used within a lamp such as for example an A-19 light bulb.

The lighting module 10 comprises a wireless controller 16; a two-color LED array 18 comprising a plurality, x, of first LEDs designated A₁ . . . Aₓ that generate light of a first color/color temperature and a plurality, y, of second LEDs designated B₁ . . . B_{y} that generate light of a second color/color temperature; a first LED driver 20 for operating (driving) the first LEDs A₁ . . . Aₓ; and a second LED driver 22 for operating (driving) the second LEDs B₁ . . . B_{y}. As indicated in FIG. 1, the plurality of first and second LEDs can be serially connected though it will be appreciated that they can be connected in other configurations. In accordance with the invention, the wireless controller 16; the two color LED array 18; the first LED driver 16; and the second LED driver 18 are mounted on a single a circuit board 24, typically a MCPCB (Metal Core Printed Circuit Board).

The wireless controller 16 comprises an antenna 26 for receiving the wireless control signal 12 (Ctrl); a transceiver 28 and controller logic 30 for generating a respective control signal DimA and DimB for operating the first and second LED drivers 20, 22 in response to the received control signal 12. The controller logic 30 comprises a provider's firmware/software and each outputs analog or PWM signal(s) that are input directly to a respective LED driver. The remote device can wirelessly communicate with the wireless controller 16 using any transmission form such as for example a 2.4 GHz or 5 GHz Bluetooth or Wi-Fi protocol. The remote device can comprise a dedicated controller such as a handset or may be a cell phone or other Bluetooth or Wi-Fi enabled device.

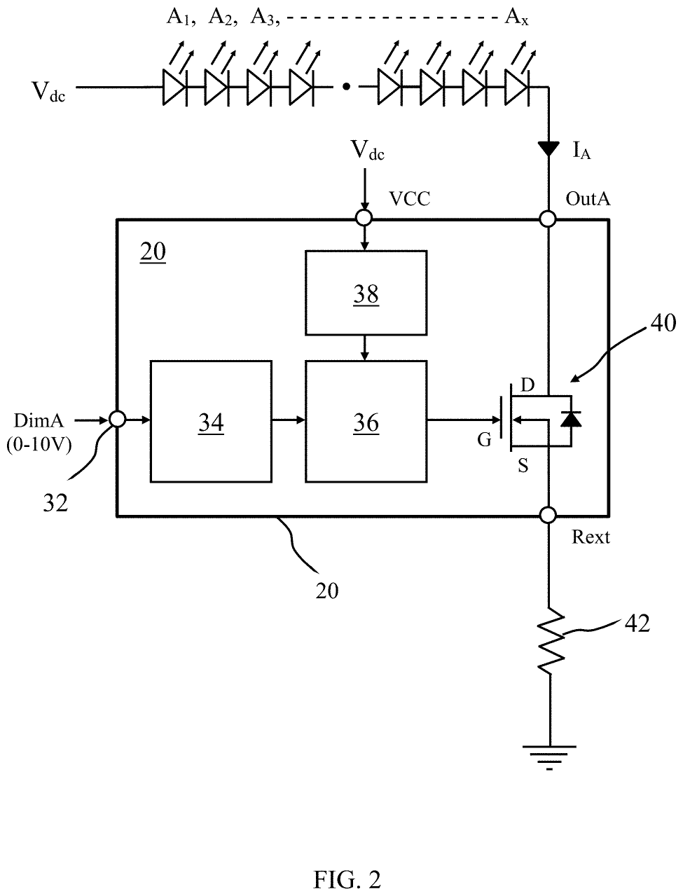

FIG. 2 shows a block diagram of an LED driver. Since the first and second LED drivers are identical, and for the sake of brevity, only the first LED driver 20 is described and it will be appreciated that the following description applies equally to both the first and second LED drivers 20, 22. Each LED driver 20, 22 can comprise a “linear” driver (linear power regulator). In this specification, a “linear” power regulator/driver is defined as a power regulator that operates in a current control mode and produces a constant-current output IA. A linear regulator is to be contrasted with a “switching” regulator that operates in a constant power control mode (e.g. a switch mode power supply) that produces a switched (modulated) output current.

The LED driver 20 comprises a dimmer control input 32 for receiving the dimming control signal DimA generated by the wireless controller 16. As indicated in FIG. 2, the dimming control signal DimA can be an analog control signal having a value of between 0 and 10V. In other embodiments the dimming control signal DimA can be a digital control signal such as DALI as described above. The LED driver 20 further comprises detection circuitry 34; control logic 36; a voltage regulator 38 for operating the control logic 36; and a high voltage MOSFET 40. The detection circuitry 34 detects the value of the control signal DimA (e.g. a voltage value from 0-10V in the case of an analog control signal) and converts this to a digital value. The control logic 36 converts this digital value to a corresponding voltage that is applied to the gate, G, of the MOSFET 40 to set the constant-current I_{A} passing through the MOSFET and LEDs A₁ to Aₓ to an appropriate value. For example, if DimA is 10V the control logic will set the constant-current I_{A} to its maximum value, if DimA is 5V it might set the constant current-current I_{A} to 50% of its maximum value and if DimA is 0V it will switch off the MOSFET 40 so that no current flows through the LEDs A₁ to Aₓ. The maximum value of the constant-current I_{A} that the driver can generate can be set by an externally connected resistor 42 connected between ground and the source, S, of the MOSFET 40.

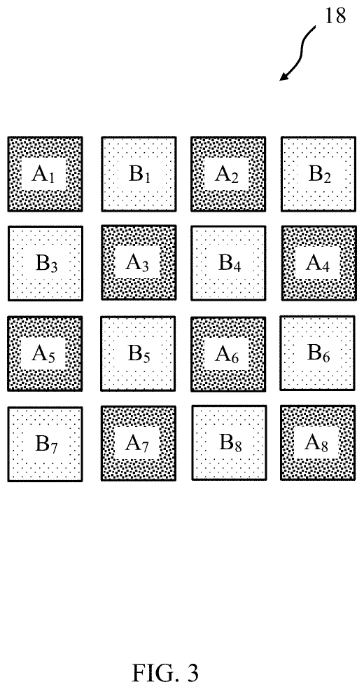

As described above, the lighting module comprises a two-color LED array 18 comprising a plurality, x, of first LEDs designated A₁ . . . Aₓ and a plurality, y, of second LEDs designated B₁ . . . B_{y}. FIG. 3 is a schematic representation of a two-color LED array 18 comprising eight (x=8) first LEDs designated A₁ to A₈ and eight (y=8) second LEDs B₁ to B₈. As indicated in the figure, the first and second LEDs are configured as a square array in rows and columns and configured such that both rows and columns comprise alternating first and second LEDs. Such an arrangement can maximize color uniformity of light output across the array. In other configurations, the array can comprise rows or columns of alternating first and second LEDs. It will be appreciated that while typically there will be an equal number of first and second LEDs (i.e. x=y) in other arrangements, there can be differing numbers of first and second LEDs.

The first LEDs and second LEDs can generate white light of different CCTs (Correlated Color Temperature). Such an arrangement enables light generated by the LED module to be controlled between the two color temperatures and color temperatures there between. For example, the first LEDs may generate Cool White (CW) light, and the second LEDs may generate Warm White (WW) light enabling control of light generated by the LED module between WW and CW and color temperatures there between. In this patent specification,

Cool White is defined as white light having a CCT (Correlated Color Temperature) of between about 4500K to about 6000K and Warm White is defined as white light having a CCT of between about 2700K to about 4000K. More particularly, the first LEDs generate Cool White light having a color temperature of 5000K to 5500K and the second LEDs generate Warm White light having a color temperature of 2700K to 3000K. Table 1 tabulates values of lighting module output, CCT (K), brightness (%) and dimming (%) as a function of LED Driver control signal. The table illustrates how the color temperature and dimming level of the lighting module can be controlled using the driver control signals DimA and DimB. The data of the table is for a lighting module in which the first LEDs A₁ to Aₓ generate light having a CCT of 5000K (CW), the second LEDs B₁ to B_{y} generate light having a CCT of 2700K (WW) and the driver control signals, DimA and DimB, comprise an analog voltage between 0V and 10V. It can be seen that the color temperature of light generated by the lighting module can be controlled by adjusting the relative magnitudes of DimA and DimB and the dimming level controlled by adjusting the magnitude of the sum of DimA and DimB.

TABLE 1
Lighting module output CCT, Brightness, and Dimming
as a function of LED driver control signal

| Driver control signal | | Lighting module output | | |
|---|---|---|---|---|
| DimA (V) | DimB (V) | CCT (K) | Brightness (%) | Dimming (%) |
| 10.0 | 0 | 5000 | 100 | 0 |
| 7.5 | 2.5 | 4000 | 100 | 0 |
| 5.0 | 5.0 | 3500 | 100 | 0 |
| 2.5 | 7.5 | 3000 | 100 | 0 |
| 0 | 10.0 | 2700 | 100 | 0 |
| 5.0 | 5.0 | 3500 | 100 | 0 |
| 4.0 | 4.0 | 3500 | 80 | 20 |
| 3.0 | 3.0 | 3500 | 60 | 40 |
| 2.0 | 2.0 | 3500 | 40 | 60 |
| 1.0 | 1.0 | 3500 | 20 | 80 |

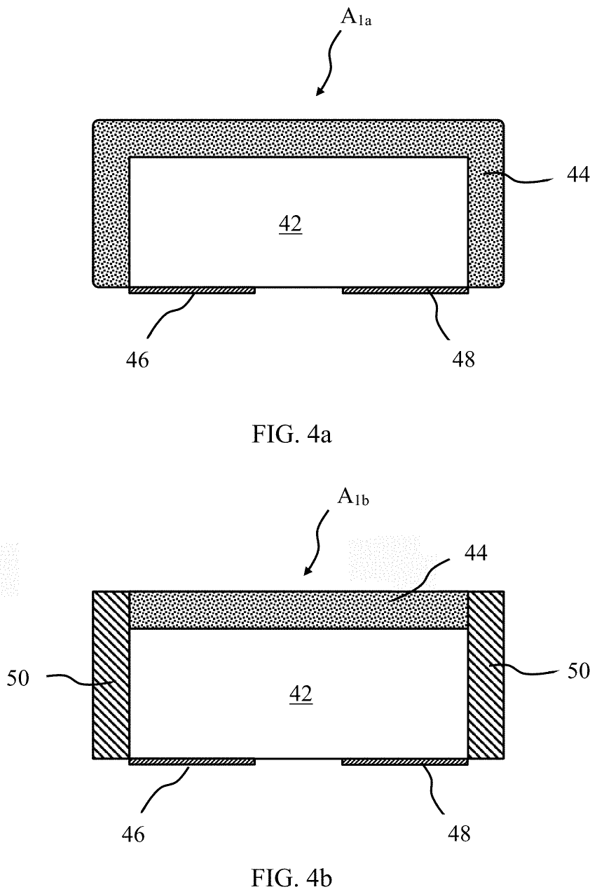

In other embodiments, the first LEDs can generate white light with a first CCT and the second LEDs can generate light of a particular color (i.e. other than white) for modifying the color temperature of light generated by the first LEDs. For example, the first LEDs may generate Cool White (CW) light, and the second LEDs may generate red light. It will be appreciated that by increasing the amount of red light will decrease the color temperature of light generated by the lighting module allowing control of light generated by the LED module between CW and WW and color temperatures there between.

Where the first and/or second LEDs generate white light they can comprise photoluminescence converted LEDs (“white LEDs”) that may comprise packaged LEDs or unpackaged, so called “chip-scale packaged”, LEDs. FIGS. 4a and 4b show schematic cross-sectional side views of two configurations of “chip-scale packaged” LEDs. Since the first and second LEDs are essentially identical (the only difference being the color/color temperature of light they produce which is determined by the photoluminescence material(s) they incorporate), and for the sake of brevity, only “chip-scale packaged” first LEDs are explicitly described. It will be appreciated, however, that the following description in relation to first LEDs applies equally to second LEDs.

Referring to FIG. 4a there is shown a cross sectional side view of a “chip-scale packaged” first LED A₁ₐ in accordance with a first configuration comprising a first LED flip-chip die 42 having a photoluminescence material layer 44 on its light emitting upper face and side faces. On its lower face, the LED flip chip die 42 comprises respective contact pads 46, 48 for the anode and cathode of the LED chip die. The LED flip chip die 42 typically comprises a InGaN/GaN-based LED chip that is operable to generate excitation light with a dominant wavelength in a range from 420 nm to 470 nm, that is, in the blue region of the visible spectrum. In other embodiments, the LED chip die can generate excitation light with a dominant wavelength in a range from 200 nm to 400 nm, that is, in the UV to violet region of the spectrum. In the case of the latter, the photoluminescence material layer can additionally include a photoluminescence material that generates light having a peak emission wavelength in the blue region of the spectrum (e.g. 420 nm to 470 nm). The photoluminescence material layer 44 typically comprises a sheet, or film, containing one or more photoluminescence materials and the sheet is laminated over the LED chip die to cover (in contact with) the light emitting upper face and side faces of the LED chip die. The photoluminescence material(s) can comprise inorganic phosphor materials, organic phosphor materials or quantum dot (QD) materials. The “chip-scale packaged” LEDs of FIG. 3 can be directly flip chip mounted to a circuit board and due to the compact form enable a compact array of LEDs to be fabricated.

Referring to FIG. 4b there is shown a “chip-scale packaged” first LED A1b in accordance with a second configuration. In this second configuration, the photoluminescence material layer 44 covers only the light emitting upper face of the LED chip die 42 and the side light emitting faces are covered with a light reflective material layer 50.

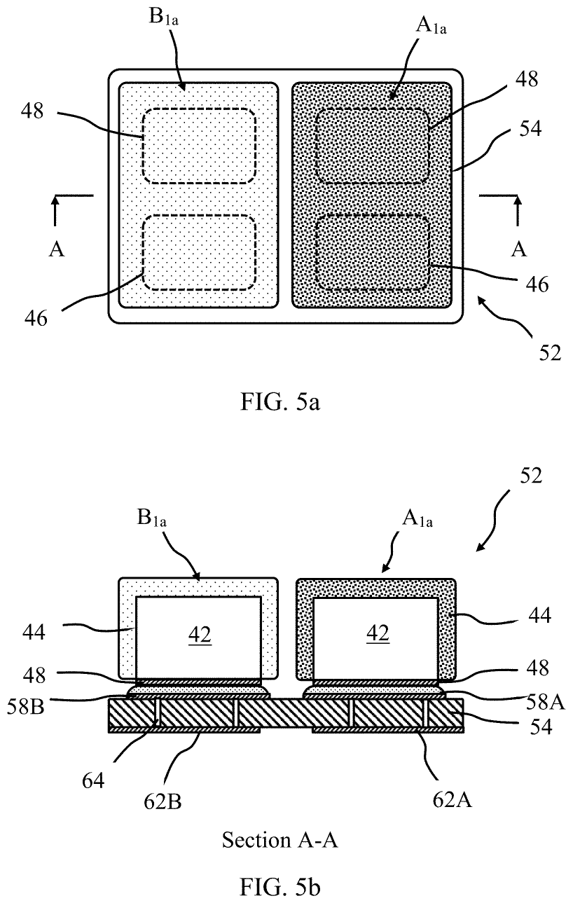

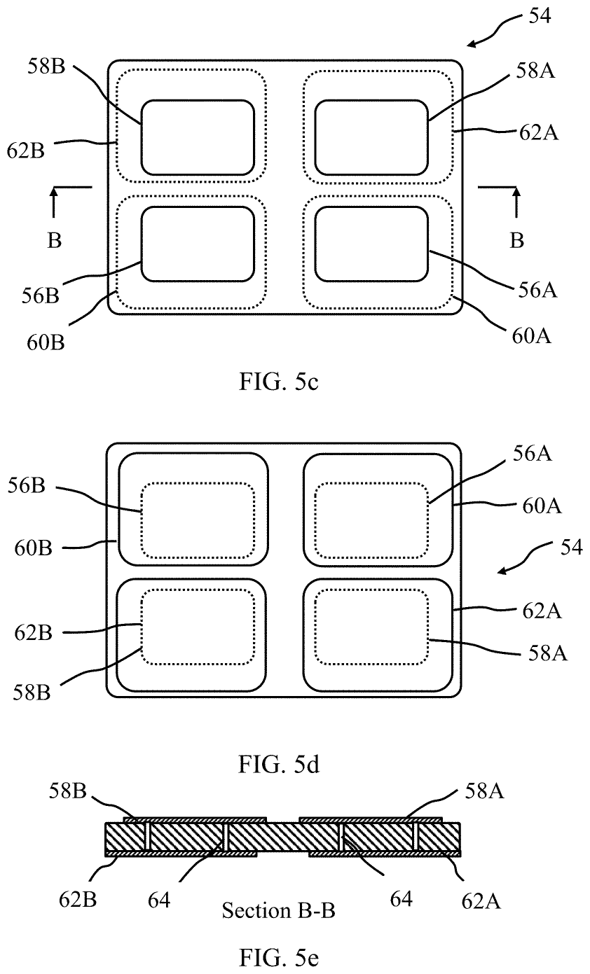

FIGS. 5a and 5b are schematic representations of a SMD (Surface Mount Device) LED module 52 respectively showing a top view and a cross sectional side view through A-A. The SMD LED module 52 comprises an assembly of a first “chip-scale packaged” LED A₁a and a second “chip-scale packaged” LED B₁a mounted on an upper face of a substrate (submount) 54. FIGS. 5c to 5e are schematic representations of the SMD LED module substrate 54 and respectively show a view of the upper face of the substrate, a view of the lower face of the substrate and a cross sectional side view through B-B. The SMD LED module 52 can, for example, comprise a 20/25 (2.0 mm by 2.5 mm) or 28/35 (2.8 mm by 3.5 mm) package format. As can be seen in FIG. 5c on the upper face of the substrate there are provided respective contact pads 56A, 56B for the anode of the first and second “chip-scale packaged” LEDs and respective electrode contact pads 58A, 58B for the cathode of the first and second “chip-scale packaged” LEDs. As can be seen in FIG. 5d on the lower face of the substrate there are provided respective electrode contact pads 60A, 60B for the anode of the first and second “chip-scale packaged” LEDs and respective electrode contact pads 62A, 62B for the cathode of the first and second “chip-scale packaged” LEDs. Corresponding contact pads on the upper and lower faces of the substrate are electrically connected by means of vias 64. For example, the cathode contact pads 56A and 60A for the first LED A1a are electrically connected by one or more vias 64. The substrate 54 can comprise a LTCC (Low Temperature Co-fired ceramic).

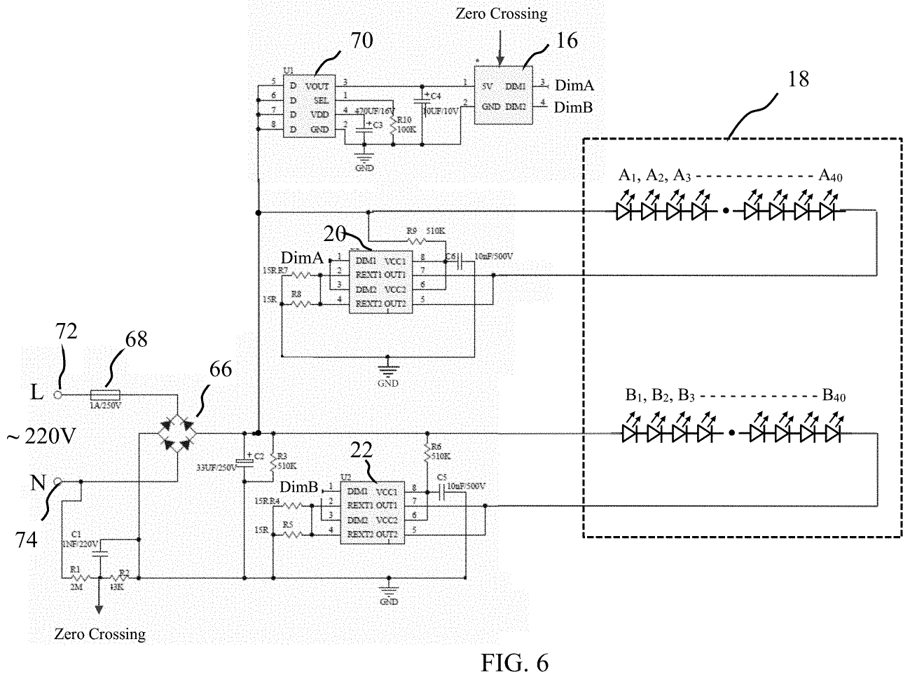

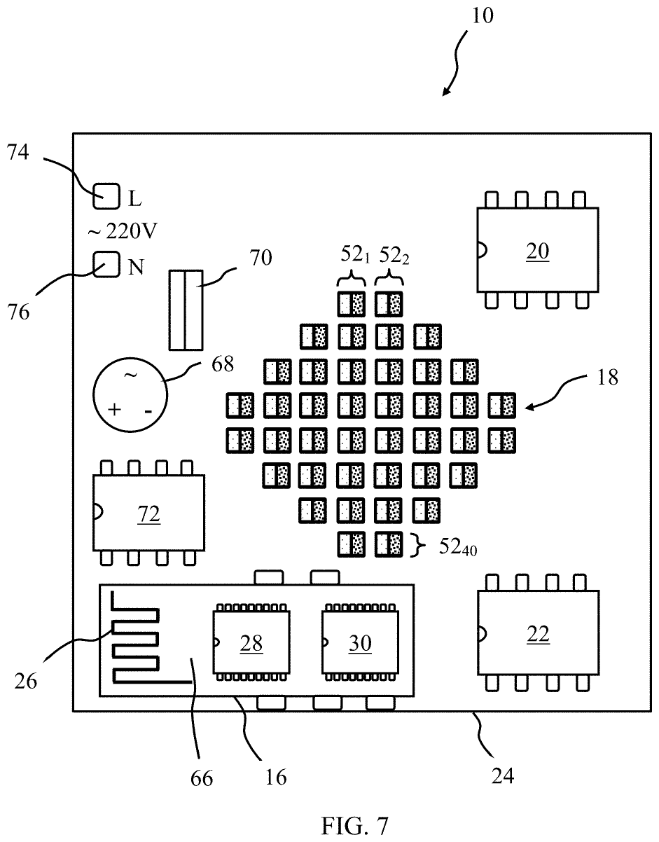

Referring to FIG. 6 there is shown a circuit diagram of a wirelessly controllable lighting module 10 according to an embodiment of the invention. The lighting module 10 can be configured for operation with a 220V 50 Hz line supply as is common in China and parts of Europe and the module is intended to be used within a lamp such as for example an A-19 light bulb. In this embodiment, the two-color LED array 18 comprises forty SMD LED modules designated 52₁ to 52₄₀ (FIG. 7), that is forty first LEDs A₁ to A₄₀ and forty second LEDs B₁ to B40. The LED drivers 20, 22 each comprise an RM9012 dimmable dual-channel constant-current LED control chip from Reactor Microelectronics (Shaanxi Reactor Microelectronics Co, Ltd). As illustrated in FIG. 6, the two channels of the control chip are connected in parallel such that the maximum constant-current is increased from 80 mA to 160 mA. In the implementation illustrated in FIG. 6, the wireless controller 16 comprises a 2.4 GHz RF Intelligent dual-channel LED controller from Sky Engineer (China) and the remote device 14 comprises a dedicated lighting control handset. As indicated in FIG. 7, the wireless controller 16 comprises a circuit board 66 carrying the antenna 26, transceiver 28 and controller logic 30. Additionally, the circuit further comprises, a bridge rectifier 68; a fuse 70; a voltage regulator 72 for operating the wireless controller 16; and live and neutral connection pads 74, 76 for connecting the LED module to a 220V 50 Hz line supply. The voltage regulator can comprise 10 KP3310 linear voltage regulator by Hi-Semicon coverts line voltage to 5V (Shenzhen Hi-Semicon Electronics Co, Ltd). FIG. 7 is a plan view of a physical implementation of the wirelessly controllable lighting module circuit of FIG. 6. The LED module 10 is fabricated of a 50 mm square MCPCB 24, upon which the components described above are mounted.

### REFERENCE NUMERALS

10 LED module
12 Wireless control signal
14 Remote device
16 Wireless controller
18 Two color LED array
A₁ to Aₓ First LEDS
B₁ to B_{y} Second LEDS
20 First LED driver
22 Second LED driver
24 MCPCB
26 Antenna
28 Transceiver
30 Controller logic
32 LED driver dimmer control input
34 Detection circuitry
36 Control logic
38 Voltage regulator
40 High voltage MOSFET
A₁a “chip-scale packaged” first LED (first configuration)
A₁b “chip-scale packaged” first LED (second configuration)
42 First LED flip chip die
44 Photoluminescence material layer
46 LED chip die contact pad (cathode)
48 LED chip die contact pad (anode)
50 light reflective material layer
52 SMD LED module
54 Ceramic substrate (submount)
56A, 56B Substrate contact pad (cathode)
58A, 58B Substrate contact pad (anode)
60A, 60B Substrate contact pad (cathode)
62A, 62B Substrate contact pad (anode)
64 Via
66 Wireless controller circuit board
68 Bridge rectifier
70 Fuse
72 Voltage regulator
74 Live
76 Neutral

What is claimed is:

1. A lighting module comprising:
a plurality of first LEDs operable to generate light of a first color temperature;
a plurality of second LEDs operable to generate light of a second color temperature;
a first LED driver for operating the plurality of first LEDs in response to a first control signal;
a second LED driver for operating the plurality of second LEDs in response to a second control signal;
a wireless controller for generating the first and second control signals in response to a control signal wirelessly receivable from a remote device; and
a circuit board;
wherein the plurality of first and second LEDs, the first and the second LED drivers and the wireless controller are mounted on the circuit board.

2. The lighting module of claim 1, wherein the first and second LED drivers comprise a linear regulator.

3. The lighting module of claim 1, wherein the first LEDs comprise unpackaged first LED chips that have an individual coating layer of a first photoluminescence material covering one or more light emitting faces of the unpackaged first LED chips.

4. The lighting module of claim 3, wherein the individual coating layer is in contact with and covers the top and side light emitting faces of the unpackaged first LED chip.

5. The lighting module of claim 3, comprising a light reflective material covering the side light emitting face of the unpackaged first LED chip, and wherein the individual coating layer is in contact with and covers the top light emitting face of the unpackaged first LED chip.

6. The lighting module of claim 1, wherein the second LEDs comprise unpackaged second LED chips that have an individual coating layer of a second photoluminescence material covering one or more light emitting faces of the unpackaged second LED chips.

7. The lighting module of claim 6, wherein the individual coating layer is in contact with and covers the top and side light emitting faces of the unpackaged second LED chip.

8. The lighting module of claim 6, comprising a light reflective material covering the side light emitting face of the unpackaged second LED chip, and wherein the individual coating layer is in contact with and covers the top light emitting face of the unpackaged second LED chip.

9. The lighting module of claim 1, wherein the first and second LEDs are mounted directly on the circuit board.

10. The lighting module of claim 1, wherein the first and second LEDs comprise an assembly having first and second LEDs mounted on a substrate and wherein the substrate is mounted on the circuit board.

11. The lighting module of claim 10, wherein the assembly consists of two LEDs mounted on the substrate.

12. The lighting module of claim 1, wherein the plurality of first LEDs are operable to generate Cool White light, and the plurality of second LEDs are operable to generate Warm White light.

13. The lighting module of claim 12, wherein the Cool White light has a color temperature of 5000K to 5500K, and the Warm White light has a color temperature of 2700K to 3000K.

14. The lighting module of claim 1, wherein the plurality of first LEDs and plurality of second LEDs are configured as an array.

15. The lighting module of claim 14, wherein the array comprises rows and columns and wherein rows comprise alternating first and second LEDs and/or columns comprise alternating first and second LEDs.

16. The lighting module of claim 1, wherein the circuit board comprises a metal core printed circuit board.

17. The lighting module of claim 1, wherein the wireless controller comprises an antenna, a transceiver, and a control module.

18. The lighting module of claim 17, wherein the antenna, the transceiver, and control module are mounted on a substrate, and wherein the substrate is mounted on the circuit board.

19. The lighting module of claim 1, wherein the wireless controller controllably adjusts the first and second control signals such that the LED module generates light with a selected dimming level and/or selected color temperature.

20. The lighting module of claim 1, wherein the wireless controller wirelessly communicates with a remote device using a Bluetooth protocol and/or Wi-Fi protocol.
